(19) United States
(12) Patent Application Publication
(10) Pub. No.: US 2007/0164428 A1
(43) Pub. Date: Jul. 19, 2007

(54) High power module with open frame package

(76) Inventors: Alan Elbanhawy, Hollister, CA (US); Benny Tjia, San Francisco, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(21) Appl. No.: 11/335,366

(22) Filed: Jan. 18, 2006

(51) Int. Cl. H01L 21/44

(52) U.S. Cl. 257/734; 438/612

(57) ABSTRACT

A semiconductor assembly is disclosed. The semiconductor assembly includes a multilayer substrate having at least two layers with conductive patterns insulated by at least two dielectric layers. The substrate includes a first surface and a second surface. A leadless package comprising a control chip is coupled to the multilayer substrate. A semiconductor die comprising a vertical transistor is coupled to the multilayer substrate. There are conductive structures on the second surface for attaching the substrate to a circuit board. The control chip and the semiconductor die are in electrical communication through the multilayer substrate.

### CROSS-REFERENCES TO RELATED APPLICATIONS NOT APPLICABLE

None.

### BACKGROUND OF THE INVENTION

Power supplies are typically used for cell phones, portable computers, digital cameras, routers, and other portable electronic systems. Some power supplies include synchronous buck converters. Synchronous buck converters shift DC voltage levels in order to provide power to programmable grid array integrated circuits, microprocessors, digital signal processing integrated circuits and other circuits, while stabilizing battery outputs, filtering noise, and reducing ripple. Synchronous buck converters are also used to provide high-current, multiphase power in a wide range of data communications, telecom, and computing applications.

As electronic devices such as computers, phones, etc. become smaller and smaller, it becomes more desirable to incorporate all or substantially all of the components for a power supply into a single semiconductor assembly or single package. The single semiconductor assembly or single package is then mounted to a motherboard.

Integrating multiple components such as power supply components into a single conventional semiconductor assembly or package is challenging. For example, many power packages are formed using molding techniques. However, it is difficult to form a molded power package with many different discrete electronic components. In addition, traditional molded power packages generally suffer from long design and qualification cycles. They also suffer from high development costs, and modifying them is also time-consuming. Lastly, traditional molded packages have relatively poor heat dissipation and electrical properties.

It would be desirable to provide for improved semiconductor assemblies and systems that can address some or all of the above-noted problems. The improved semiconductor assemblies and systems can incorporate all or substantially all of the components of a power supply.

### BRIEF SUMMARY OF THE INVENTION

Embodiments of the invention are directed to semiconductor assemblies, methods for making semiconductor assemblies, and systems using semiconductor assemblies.

One embodiment of the invention is directed to a semiconductor assembly comprising a multilayer substrate having at least two layers with conductive patterns insulated by at least two dielectric layers. The multilayer substrate also includes a first surface and a second surface. A leadless package comprising a control chip, and a semiconductor die comprising a vertical transistor is also coupled to the multilayer substrate. The control chip and the semiconductor die are in electrical communication through the multilayer substrate. Conductive structures are on the second surface and electrically couple the substrate to a circuit board.

Another embodiment of the invention is directed to a method for making a semiconductor assembly. The method includes obtaining a multilayer substrate having at least two layers with conductive patterns insulated by at least two dielectric layers. The substrate includes a first surface and a second surface. Once the substrate is obtained, a leadless package comprising a control chip, and a semiconductor die comprising a vertical transistor are attached to the multilayer substrate. Conductive structures are also attached to the second surface. The conductive structures electrically couple the substrate to a circuit board.

These and other embodiments of the invention are described in further detail below.

### BRIEF DESCRIPTION OF THE DRAWINGS

FIG. 1 shows a top plan view of a multilayer substrate according to an embodiment of the invention.

FIG. 2 shows a top plan view of a semiconductor assembly according to an embodiment of the invention.

FIG. 3 shows a schematic side view of a semiconductor assembly according to an embodiment of the invention.

FIG. 4 show a perspective view of a system according to an embodiment of the invention.

FIG. 5 shows a bottom plan view of another semiconductor assembly according to an embodiment of the invention.

FIG. 6 shows a top plan view of the semiconductor assembly embodiment shown in FIG. 5.

FIG. 7 shows a side view of a semiconductor assembly of the type shown in FIGS. 5 and 6.

FIGS. 8-9 show exemplary circuit diagrams associated with exemplary semiconductor assemblies according to embodiments of the invention.

FIGS. 10(a)-10(h) show various views of conductive layers that can be present in a multilayer substrate according to an embodiment of the invention.

FIG. 11 shows a graph of an efficiency curve associated with a four phase power module that has a configuration like the one shown in FIG. 2.

### DETAILED DESCRIPTION OF THE INVENTION

Embodiments of the invention are directed to semiconductor assemblies, methods for making semiconductor assemblies, and systems that use the semiconductor assemblies. The semiconductor assemblies according to embodiments of the invention can be turned around very fast, and can be custom designed without long and expensive development cycles. This can be accomplished by mounting components for a power subsystem or a complete power system on a multilayer substrate (e.g., a multilayer PCB or printed circuit board). The multilayer substrate can be constructed with an optimal layout to minimize parasitics and thermal resistance, while optimizing performance. Once the semiconductor assembly is constructed, it may be reflow soldered to any suitable motherboard using a standard reflow process to form an electrical system.

The semiconductor assemblies according to embodiments of the invention may be viewed as electrical subsystems in some cases. Such subsystems can be used with motherboards with fewer conductive and insulating layers. By using a semiconductor assembly with a multilayer substrate, a manufacturer of an electrical system need not worry about the design or layout of any circuit patterns that are needed to connect the components that are otherwise present in the semiconductor assembly. Put another way, if a multilayer substrate is not present, then the circuitry that is needed to interconnect discrete dies in a power supply would have to be present in the motherboard, thereby increasing the complexity of the motherboard.

Using embodiments of the invention, it is possible to effectively introduce components that can perform at high efficiency, even if the motherboard does not have enough layers to achieve optimum performance. Since a semiconductor assembly according to an embodiment of the invention uses a multilayer substrate with multiple conductive and insulating layers, fewer conductive and insulating layers may be used in the motherboard. For example, when a semiconductor assembly including a multilayer substrate with four conductive layers is mounted to a motherboard, the motherboard may contain four conductive layers, rather than eight conductive layers, since four conductive, patterned layers are already present in the semiconductor assembly. This reduces manufacturing costs, since motherboards with four conductive layers are less expensive than motherboards with eight conductive layers. The reduction of manufacturing costs is particularly desirable in the computer industry where profit margins are often narrow.

A semiconductor assembly according to an embodiment of the invention can be designed with the best interconnection scheme possible, while reducing parasitic resistance and inductance. Parasitic resistance and inductance can be a significant contributing factor to losses in power conversion efficiency. To reduce parasitic resistance and inductance, the conductive layers in a multilayer substrate may occupy a large proportion (e.g., 50% or more) of the planar area of the multilayer substrate. The plural conductive layers in the multilayer substrate may also be interconnected by a plurality of conductive vias. If a multilayer substrate in a semiconductor assembly includes, for example, 8 layers of wide, 1 ounce, patterned copper, and contains 50 or more conductive vias, the multilayer substrate behaves as a unitary piece of copper, thereby reducing parasitics and thermal resistance.

Embodiments of the invention have other advantages. For example, the semiconductor assemblies according to embodiments of the invention do not need wirebonds to interconnect electrical components as in conventional packages. This reduces the cost and complexity of the manufacturing process. Also, compared to conventional packages, the semiconductor assemblies according to embodiments of the invention are very easy to make, install, and check for defects, since there is no molding covering the electrical components in them. From a design point of view, the “open frame” or “unmolded” electrical assemblies according to embodiments of the invention can be designed and created in as little as a few days or a couple of weeks, since standard circuit board design techniques are used. In comparison, new molded package designs may take months to design, qualify and implement.

As noted above, the multilayer substrates that are used in embodiments of the invention can be fabricated using traditional circuit board manufacturing techniques. Consequently, an electrical assembly according to an embodiment of the invention can be optimized or shaped for a particular motherboard, since the electrical assembly uses a multilayer substrate instead of a leadfrarne as a support. For example, the multilayer substrate and the corresponding electrical assembly may be shaped as a square, L, X, O, or any other suitable shape. It is not possible or very difficult to create molded packages with such shapes using traditional leadframes, since leadframes have predetermined configurations.

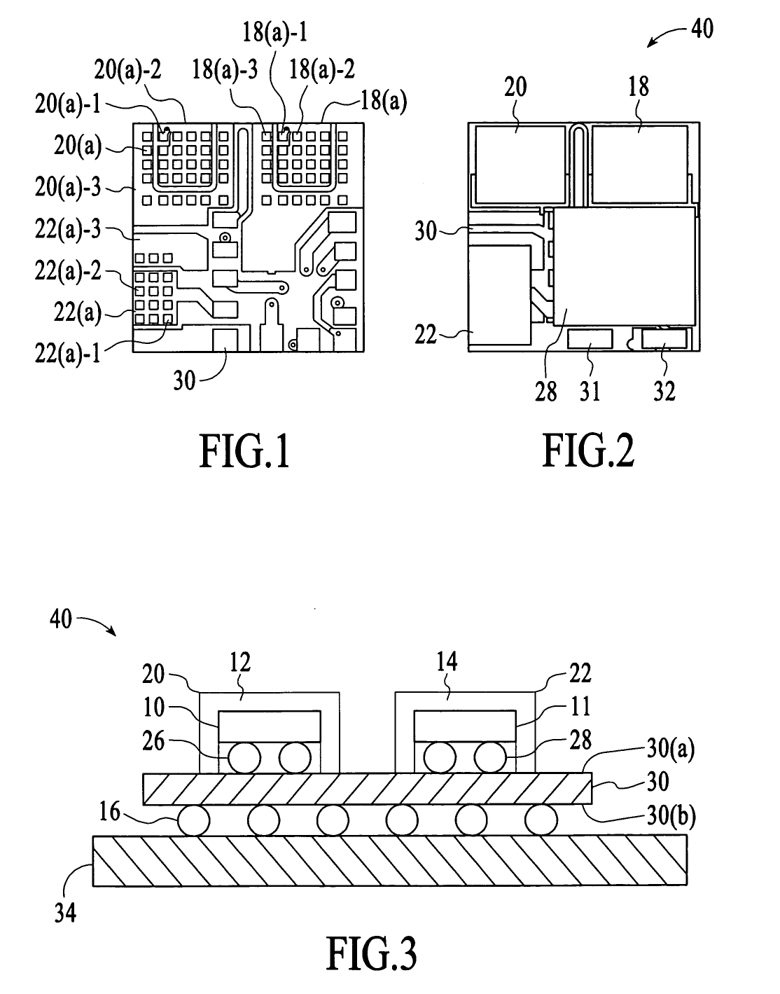

FIG. 1 shows a top plan view of a multilayer substrate 30 according to an embodiment of the invention, prior to mounting components on it. The multilayer substrate 30 includes low side transistor attachment regions 18(a), 20(a) and a high side transistor attachment region 22(a). Each low side attachment region 18(a), 20(a) has at least one gate attach region 18(a)-1, 20(a)-1, at least one source attach region 18(a)-2, 20(a)-2, and at least one drain attach region 18(a)-3, 20(a)-3. The high side transistor attachment region 22(a) has at least one gate attach region 22(a)-1, at least one source attach region 22(a)-2, and at least one drain attach region 22(a)-3. Although two low side transistor attachment regions and one high side transistor attachment regions are shown in this example, it is understood that any number of high and low side transistor attachment regions may be present in the multilayer substrate in embodiments of the invention. As shown in FIG. 1, the conductive pattern formed by such contact areas may occupy at least 50% (e.g., at least about 75%) of the planar dimensions of the multilayer substrate 30. Alternatively or additionally, as large a conductive area as possible could be used.

In embodiments of the invention, the multilayer substrate 30 can have at least two layers with conductive patterns insulated by at least two dielectric layers. There may be at least “n” (e.g., at least four) layers with conductive patterns insulated by at least “m” (e.g., at least three) dielectric layers, wherein each of n and m are two or more. The thickness of each individual conductive and/or insulating layer may vary in embodiments of the invention. The multilayer substrate 30 may also include a first, external surface which faces away from a motherboard to which it is mounted, and a second, external surface which faces towards the motherboard.

The multilayer substrate 30 may also comprise any suitable material. For example, the conductive layers 30 in the multilayer substrate 30 may comprise copper (e.g. sheets of one ounce copper), aluminum, noble metals, and alloys thereof. The insulating layers in the multilayer substrate 30 may comprise any suitable insulating material, and may be reinforced with appropriate fillers (e.g., fabrics, fibers, particles). Suitable insulating materials include polymeric insulating materials such as FR4 type materials, polyimide, as well as ceramic insulating materials.

The multilayer substrate 30 may also have any suitable dimensions and/or configuration. As noted above, the planar configuration of the multilayer substrate 30 may be a square, rectangle, circle, polygon (e.g., L-shaped), etc. The total thickness of the multilayer substrate 30 may be about 2 mm or less in some embodiments.

FIG. 2 shows a top plan view of a semiconductor assembly 40 according to an embodiment of the invention, after various components have been mounted on the multilayer substrate 30 shown in FIG. 1. The semiconductor assembly 40 may form a complete or partial synchronous buck converter subsystem. Specifically, FIG. 2 shows a synchronous buck converter subsystem comprising one high side and two low side MOSFET die packages as well as a power bypass capacitor and a bootstrap capacitor on a 10 mm×10 mm PCB (printed circuit board). The PCB includes eight conductive layers and has a total thickness of about 2 mm.

Referring to FIG. 2, the semiconductor assembly 40 may include two low side transistor packages 18, 20, and a high side transistor package 22 mounted on the first surface of the multilayer substrate 30. A packaged control chip 28, and two capacitors 31, 32 may also be mounted to the first surface of the multilayer substrate 30.

The transistor packages 18, 20, 22, and the packaged control chip 28 are preferably BGA (ball grid array) type packages. A BGA type package has an array of solder balls (or other solder structures) on a semiconductor die and the die is flip chip mounted on the multilayer substrate 30. Examples of BGA type packages are described in U.S. Pat. No. 6,133,634, which is assigned to the same assignee as the present invention. A BGA type package may be considered a “leadless” package, since it does not have discrete leads that extend laterally away from a molding material.

FIG. 3 shows a side view of a system including a semiconductor assembly 40 of the type shown in FIG. 2 mounted on a motherboard 34. The motherboard 34 may be a multilayer printed circuit board or the like. The multilayer substrate 30 includes a first surface 30(a) that faces away from the motherboard 34 and a second surface 30(b) that faces toward the motherboard 34. For clarity of illustration, the individual layers in the multilayer substrate 30 are not shown in FIG. 3.

A number of conductive structures 16 may be used to electrically and mechanically couple the second surface 30(b) of the multilayer substrate 30 to the motherboard 34. The conductive structures 16 may be in the form of solder balls, solder columns, conductive pins, conductive traces, etc. Suitable solder balls and solder columns may comprise lead based solder, or lead free solder. If the conductive structures 16 include solder, the solder in the conductive structures 16 may have lower melting points than solder (e.g., 26, 28) that is used to connect discrete components to the substrate 30.

A number of packaged components are mounted on the first surface 30(a) of the multilayer substrate 30. The packaged components include a low side transistor package 20 and a high side transistor package 22. The low side transistor package 20 includes a semiconductor die 10 which may comprise a vertical power transistor. The high side transistor package 22 may also include a semiconductor die 11, which may also comprise a vertical power transistor.

Vertical power transistors include VDMOS transistors and vertical bipolar transistors. A VDMOS transistor is a MOSFET that has two or more semiconductor regions formed by diffusion. It has a source region, a drain region, and a gate. The device is vertical in that the source region and the drain region are at opposite surfaces of the semiconductor die. The gate may be a trenched gate structure or a planar gate structure, and is formed at the same surface as the source region. Trenched gate structures are preferred, since trenched gate structures are narrower and occupy less space than planar gate structures. During operation, the current flow from the source region to the drain region in a VDMOS device is substantially perpendicular to the die surfaces.

In addition to the semiconductor die 10, the low side transistor package 20 includes a drain clip structure 12 which routes drain current from an upper first surface of the semiconductor die 10 to a drain attach region (e.g., see the drain attach region 20(a)-3 in FIG. 1) on the multilayer substrate 30. In some embodiments, other conductive structures (e.g., conductive wires) can be used connect one or more electrical terminals at the upper first surface of the semiconductor die 10 to the drain attach region. Solder balls 26 (or other suitable conductive structures) may electrically and mechanically couple source and gate regions at a second, bottom surface of the semiconductor die 10 to respective source and gate attach regions on the multilayer substrate 30 (e.g., see the gate and source attach regions 20(a)-1, 20(a)-2 in FIG. 1).

In addition to the semiconductor die 11, high side transistor package 22 includes a drain clip structure 14 which routes drain current from an upper first surface of the semiconductor die 11 to a drain attach region (e.g., see the drain attach region 22(a)-3 in FIG. 1) on the multilayer substrate 30. In some embodiments, other conductive structures (e.g., conductive wires) can be used connect one or more electrical terminals at the upper first surface of the semiconductor die 10 to the drain attach region. Solder balls 28 (or other suitable conductive structures) may electrically and mechanically couple source and gate regions at a second, bottom surface of the semiconductor die 11 to respective source and gate attach regions on the multilayer substrate 30 (e.g., see the gate and source attach regions 22(a)-1, 22(a)-2 in FIG. 1).

As shown in FIG. 3, the semiconductor assembly 40 is “unmolded” or does not have a molding material that covers the various electronic components. In this regard, it may be referred to as an “open frame” assembly in some cases.

The semiconductor assembly 40 can be formed using any suitable method. In some embodiments, a multilayer substrate 30 having at least two layers with conductive patterns insulated by at least two (or possibly one) dielectric layers is obtained. The substrate includes a first surface and a second surface. The multilayer substrate 30 can be formed using lamination, deposition, photolithography, and etching processes which are well known in the art of printed circuit boards. Thus, the multilayer substrate 30 can be manufactured using known processes, or may be otherwise obtained (e.g., purchased from a vendor).

After obtaining the multilayer substrate 30, a leadless package comprising a control chip to the multilayer substrate, and a semiconductor die comprising a vertical transistor to the multilayer substrate 30 are attached to the multilayer substrate 30. As will be discussed in further detail below, more than two dies or chips can be mounted to the multilayer substrate 30, and they may be mounted to the first, top surface 30(a), or the second, bottom surface 30(b) of the multilayer substrate 30. Conductive structures 16 are also mounted on the second surface 30(b). Once completed, the semiconductor assembly 40 may be mounted to the motherboard 34.

It is also noted that the mounting of components such as the conductive structures 16, as well as any electronic components such as a packaged control chip, semiconductor dies including vertical transistors, capacitors, inductors, etc., may take place in any suitable order. For example, a control chip may be mounted to the multilayer substrate 30 first, and one or more semiconductor dies with vertical power transistors may be mounted on the multilayer substrate after this (or vice-versa). Additionally, traditional reflow soldering processes are used to mount the electronic components to the multilayer substrate in preferred embodiments of the invention.

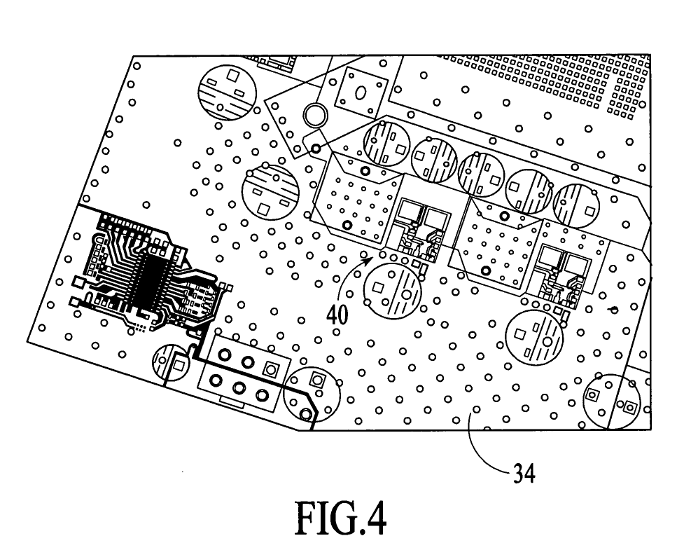

FIG. 4 shows a perspective view of a system including a motherboard 34 and two semiconductor assemblies 40 mounted on the motherboard 34. Any number of semiconductor assemblies 40 may be mounted on the motherboard 34. In embodiments, of the invention, the semiconductor assemblies can advantageously deliver up to or greater than 160 amps of current, without significant loss of power.

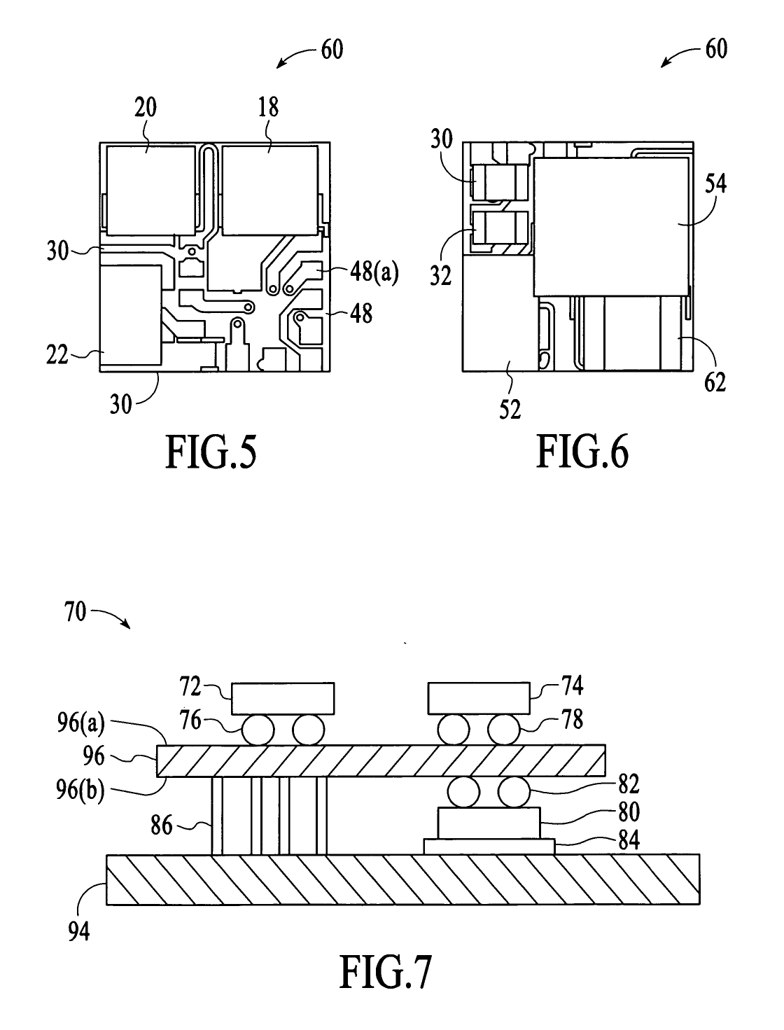

FIG. 5 shows a bottom view of another semiconductor assembly 60 according to another embodiment of the invention. The semiconductor assembly 60 includes low side transistor packages 18, 20, and a high side transistor package 22 mounted on a second, bottom surface of the multilayer substrate 30. There is also an open region 48 with a number of conductive pads 48(a). As explained below, these conductive pads 48(a) will eventually be electrically coupled to conductive pads on a motherboard (not shown). The conductive pads 48(a) could alternatively be conductive vias or conductive pin sockets.

FIG. 6 shows a top plan view of the semiconductor assembly 60 shown in FIG. 5. The semiconductor assembly 60 includes a number of components mounted on a first, upper surface of the multilayer substrate 30. The components include an inductor 54, a number of capacitors 31, 32, 62, and a control chip 52 (e.g., a PWM or pulse width modulation controller and driver, or driver).

FIG. 7 shows a side view of a system including a semiconductor assembly 60 of the type shown in FIGS. 5-6. The semiconductor assembly 60 includes a multilayer substrate 96. Suitable features for the multilayer substrate have already been described above. The multilayer substrate 96 has a first upper surface 96(a) and a second bottom surface 96(b). The first surface 96(a) faces away from the motherboard 94, while the second surface 96(b) faces toward the motherboard 94. At least two conductive layers and at least two insulating layers are present between the first surface 96(a) and the second surface 96(b) of the multilayer substrate 96.

A number of conductive structures 86 couple the second surface 96(b) of the multilayer substrate 96 to the motherboard 94. Any suitable conductive structures can be used for this purpose. Examples of conductive structures include conductive pins, solder balls, solder columns, etc. Each conductive structure 86 may have a height greater than the height of the semiconductor die 80 and conductive structures 82 attached to the semiconductor die 80.

As shown, various semiconductor dies 72, 74 may be mounted on the first surface 96(a) of the multilayer substrate 96 using conductive structures 76, 78 such as solder balls. In some embodiments, at least one of the semiconductor dies 72, 74 is a control chip that is used to control the operation of one or more vertical power transistors mounted on the second surface 96(b) of the multilayer substrate 96.

A semiconductor die 80 comprising a vertical transistor may be mounted on the second surface 96(b) of the multilayer substrate 96 using conductive structures 82 such as solder balls. The conductive structures 82 may be attached to a first, upper surface of the semiconductor die 80, which may have source and gate regions (not shown) if the power transistor is a power MOSFET. The opposite bottom second surface of the semiconductor die 80 may have a drain region and may be directly attached to a drain pad (not shown) in the motherboard 94. A conductive layer 84 comprising solder or a conductive adhesive may electrically couple the bottom second surface of the semiconductor die 80 to a pad on the motherboard 94. Alternatively, a drain clip or the like may be attached to the second surface of the semiconductor die 80 and drain current could be routed back to the multilayer substrate 96. It may then pass to the motherboard 94 through some other conductive path (e.g., through conductive structures 86).

In FIG. 7, the conductive layer 84 can directly connect an electrical terminal (e.g., a drain terminal) to a corresponding pad (not shown) on the motherboard 94. Thus, heat generated in the semiconductor die 80 can be advantageously transferred directly to the motherboard 94, thereby resulting in improved heat dissipation. Increasing the dissipation of heat from an electrical assembly can also decrease power losses. The direct connection between the die 80 and the motherboard 94 also provides for a more direct electrical connection between these two components.

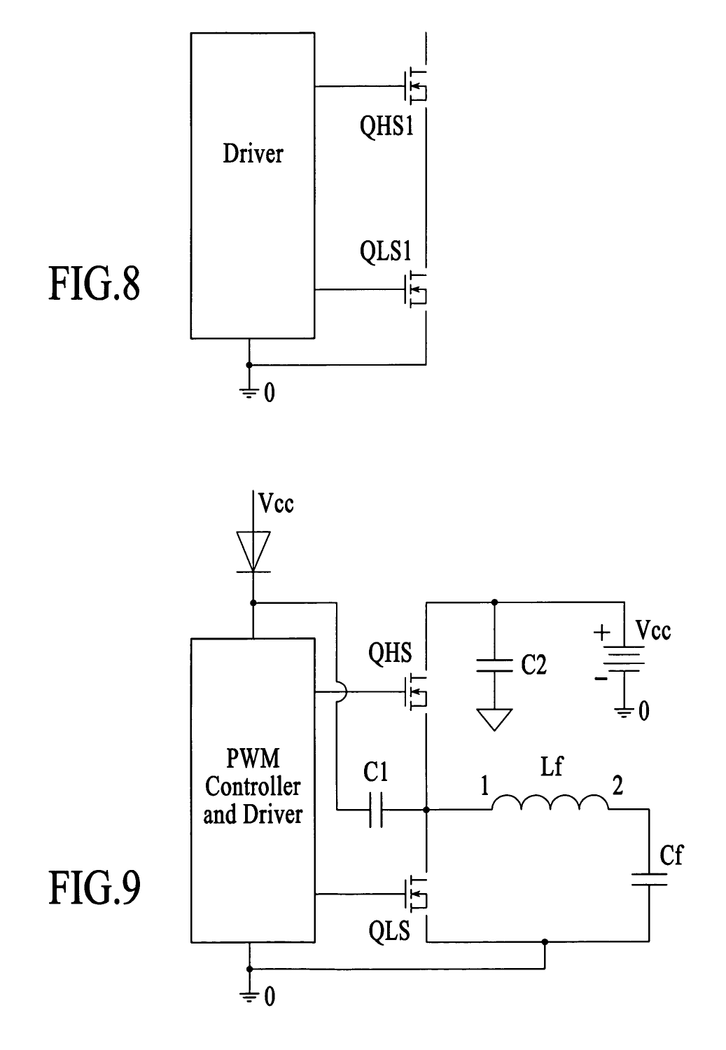

FIG. 8 shows an electrical schematic diagram of a portion of a power supply. A driver chip is shown as being operatively connected to the gates of a high side power transistor (QHS1) and a low side power transistor (QLS1). This electrical schematic can be implemented in any of the previously described electrical assemblies.

FIG. 9 shows an electrical schematic of a complete power supply or synchronous buck converter system. A control chip in the form of a PWM controller and driver is operatively connected to the gates of a low side transistor QLS and a high side transistor QHS. The drain of the low side transistor QLS is electrically connected to the source of the high side transistor QHS. It is desirable to minimize inductance between the drain of the low side transistor QLS and the source of the high side transistor QHS in order for the synchronous buck converter to be used at high operating and switching frequencies. As noted above, embodiments of the invention can minimize inductance by providing for large conductive layers and multiple vias in the multilayer substrate that supports the high and low side transistors. Various inductors and capacitors may also be present in the system. As known to those of ordinary skill in the art, such inductors and capacitors can be used to reduce noise, etc.

All of elements shown in FIG. 9 can be incorporated in the semiconductor assembly 60 shown in FIGS. 5 and 6. The reference numbers for physical components that correspond to the components in the electrical schematic in FIG. 9 are shown in parenthesis: low side transistors QLS (18, 20); high side transistor QHS (22); capacitors C1 (32), C2 (31), and Cf (62), and an inductor Lf (62). Accordingly, using embodiments of the invention, it is possible to incorporate all or substantially all of the components of a power supply into a single semiconductor assembly.

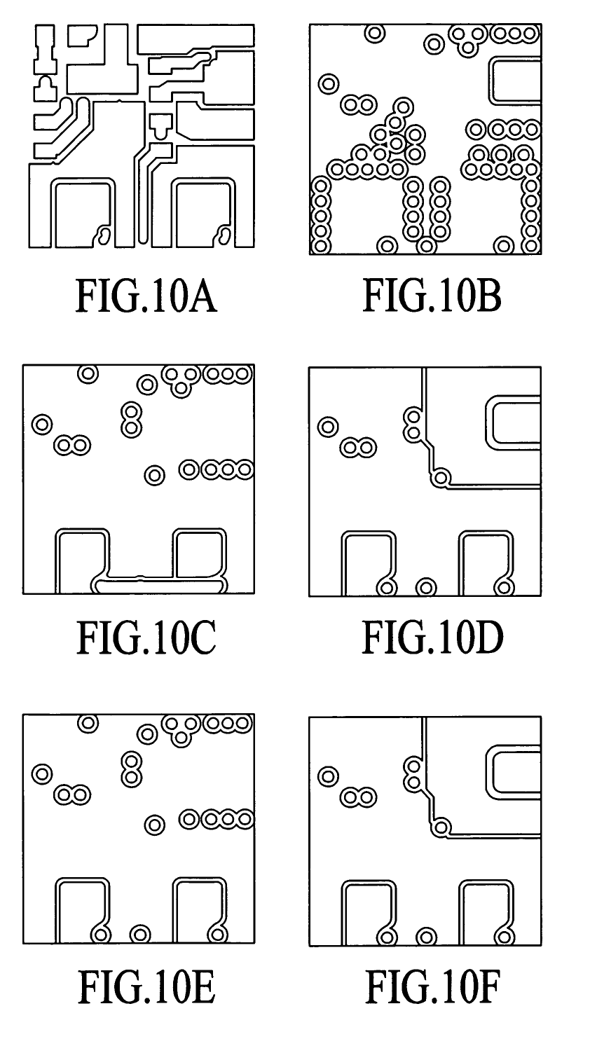

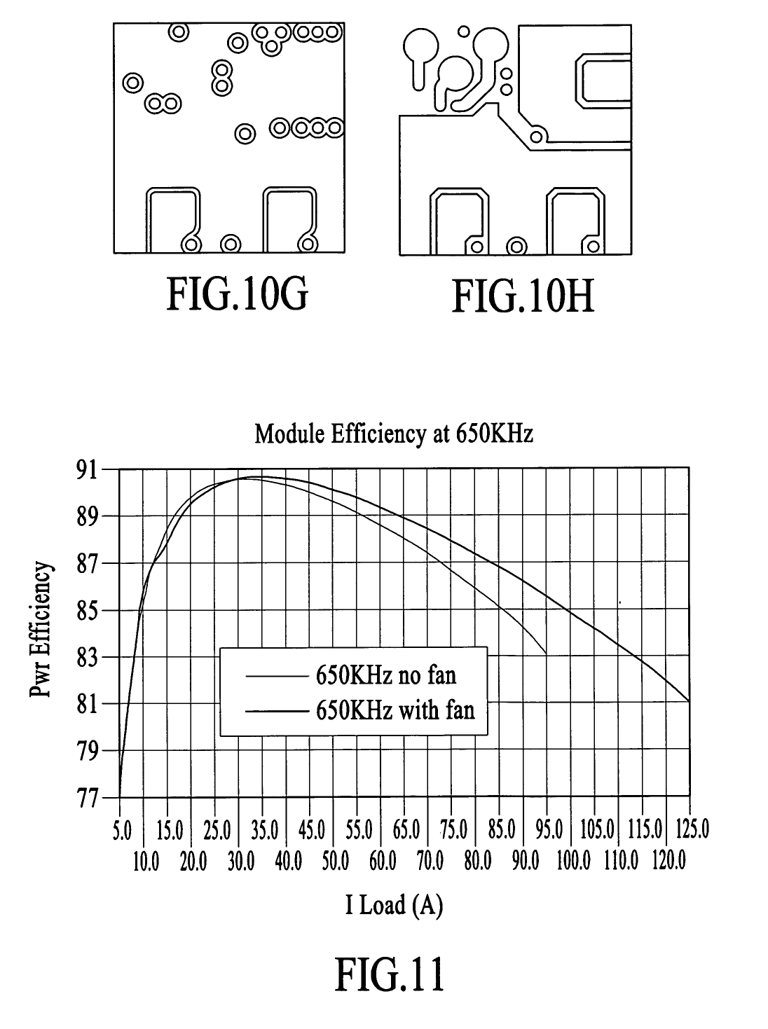

FIGS. 10(a)-10(h) show various circuit layers that can be used in a multilayer substrate according to an embodiment of the invention. In this example, there are eight conductive layers, and may conductive vias are used for interconnecting the various conductive layers. Unlike a logic type circuit board, in the multilayer substrate, the area occupied by each conductive layer occupies a substantial portion of the lateral area of the multilayer substrate.

FIG. 11 shows a graph of an efficiency curve of a four phase power module of the type shown in FIG. 2. As shown in FIG. 11, embodiments of the invention can efficiently supply high amounts of current.

Other embodiments are also possible. For example, an epoxy or other type of underfill material may be used between the substrate and a motherboard in the embodiments described above. Also, some embodiments may also use a molding material to cover one or more dies or die packages to provide for a package-like appearance.

All patent applications, patents, and publications mentioned above are herein incorporated by reference in their entirety for all purposes.

Any recitation of “a”, “an” or “the” is intended to mean “one or more” unless specifically indicated to the contrary.

The above description is illustrative but not restrictive. Many variations of the invention will become apparent to those skilled in the art upon review of the disclosure. The scope of the invention should, therefore, be determined not with reference to the above description, but instead should be determined with reference to the pending claims along with their full scope or equivalents.

What is claimed is:

1. A semiconductor assembly comprising:
a multilayer substrate having at least two layers with conductive patterns insulated by at least two dielectric layers, the substrate including a first surface and a second surface;
a leadless package comprising a control chip coupled to the multilayer substrate;
a semiconductor die comprising a vertical transistor coupled to the multilayer substrate; and
conductive structures on the second surface for attaching the substrate to a circuit board,
wherein the control chip and the semiconductor die are in electrical communication through the multilayer substrate.

2. The semiconductor assembly of claim 1 wherein the leadless package is a BGA type package.

3. The semiconductor assembly of claim 1 wherein the multilayer substrate has a lateral surface area and the conductive patterns each occupy at least 50% of the lateral surface area.

4. The semiconductor assembly of claim 1 wherein the vertical transistor is a power MOSFET.

5. The semiconductor assembly of claim 1 wherein the semiconductor die comprising the vertical transistor is mounted on the second surface of the multilayer substrate and the control chip is mounted on the first surface of the multilayer substrate.

6. The semiconductor assembly of claim 1 wherein the semiconductor assembly forms a complete power supply.

7. The semiconductor assembly of claim 1 wherein the semiconductor die is a first semiconductor die and wherein the vertical transistor is a first vertical transistor and is a high side transistor, and wherein the semiconductor assembly further comprises a second die comprising second transistor which is a low side transistor, the high side transistor and the low side transistor being controlled by the control chip.

8. The semiconductor assembly of claim 1 wherein the semiconductor die is a first semiconductor die and wherein the vertical transistor is a first vertical transistor and is a high side transistor, and wherein the semiconductor assembly further comprises a second die comprising second transistor which is a low side transistor, the high side transistor and the low side transistor being controlled by the control chip, wherein the first and second semiconductor dies are packaged in BGA packages.

9. A system comprising:
the semiconductor assembly of claim 1; and
the circuit board.

10. A method for making a semiconductor assembly comprising:
obtaining a multilayer substrate having at least two layers with conductive patterns insulated by at least two dielectric layers, the substrate including a first surface and a second surface;
attaching a leadless package comprising a control chip to the multilayer substrate;
attaching a semiconductor die comprising a vertical transistor to the multilayer substrate; and
attaching structures on the second surface for electrically coupling the substrate to a circuit board.

11. The method of claim 10 wherein the leadless package is a BGA type package.

12. The method of claim 11 wherein the multilayer substrate has a lateral surface area and the conductive patterns each occupy at least 50% of the lateral surface area.

13. The method of claim 10 wherein the multilayer substrate has a lateral surface area and the conductive patterns each occupy at least 50% of the lateral surface area.

14. The method of claim 10 wherein the vertical transistor is a power MOSFET.

15. The method of claim 10 wherein the semiconductor die comprising the vertical transistor is mounted on the second surface of the multilayer substrate and the control chip is mounted on the first surface of the multilayer substrate.

16. The method of claim 10 wherein the semiconductor assembly forms a complete power supply.

17. The method of claim 10 wherein the semiconductor die is a first semiconductor die and wherein the vertical transistor is a first vertical transistor and is a high side transistor, and wherein the semiconductor assembly further comprises a second die comprising second transistor which is a low side transistor, the high side transistor and the low side transistor being controlled by the control chip.

18. The method of claim 10 wherein the semiconductor die is a first semiconductor die and wherein the vertical transistor is a first vertical transistor and is a high side transistor, and wherein the semiconductor assembly further comprises a second die comprising second transistor which is a low side transistor, the high side transistor and the low side transistor being controlled by the control chip, wherein the first and second semiconductor dies are packaged in BGA packages.

19. A method for forming a system comprising:
forming the semiconductor assembly of claim 1; and
mounting the semiconductor assembly to the circuit board.
